(19) United States
(12) Patent Application Publication
(10) Pub. No.: US 2025/0131167 A1
(43) Pub. Date: Apr. 24, 2025

(54) PROMPT SUGGESTIONS BASED ON HISTORY AND LARGE LANGUAGE MODEL KNOWLEDGE

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/924,169

(22) Filed: Oct. 23, 2024

Related U.S. Application Data
(60) Provisional application No. 63/592,877, filed on Oct. 24, 2023.

(51) Int. Cl. G06F 30/27; G06F 30/12

(52) U.S. Cl. CPC G06F 30/27; G06F 30/12

(57) ABSTRACT

In various embodiments, a computer-implemented method for generating prompt inputs that describe design modifications includes receiving a first prompt input that indicates a first modification to a three-dimensional (3D) design, determining a first context input based on one or more attributes of the 3D design, and causing a first generative machine learning (ML) model to generate a second prompt input based on the first prompt input and the first context input, where the second prompt input indicates a second modification to the 3D design.

### CROSS-REFERENCE TO RELATED APPLICATIONS

This application claims priority benefit of the United States Provisional Patent Application titled “PROMPT SUGGESTIONS BASED ON HISTORY AND LARGE LANGUAGE MODEL KNOWLEDGE,” filed on Oct. 24, 2023, and having Ser. No. 63/592,877. The subject matter of this related application is hereby incorporated herein by reference.

### BACKGROUND

### Field of the Various Embodiments

The various embodiments relate generally to computer-aided design and artificial intelligence and, more specifically, to prompt suggestions based on history and large language model knowledge.

### Description of the Related Art

Generative machine learning (ML) models are becoming increasingly integrated into conventional software applications. Text prompts are a common way for users to interact with a generative ML model in order to perform various operations within a given software application. In a typical interaction, a user inputs a text prompt to a generative ML model, and in response, the generative ML model performs an operation within the software application on behalf of the user. Oftentimes, the operation does not satisfy the needs of the user or is incorrect for other reasons. The user typically then provides an additional text prompt to the generative ML model, thereby causing the generative ML model to respond by performing an additional operation. Interactions of this nature can repeat numerous times, in a trial-and-error manner, until the generative ML model performs an operation that meets the needs of the user.

The iterative trial-and-error process described above can become exceedingly complicated because conventional generative ML models do not necessarily behave in a deterministic or predictable manner. As such, the user oftentimes does not understand what types of prompts should be input to the generative ML model to elicit useful responses. Further, users usually cannot anticipate what operations the generative ML model is going to perform when provided with a given prompt. Consequently, successive iterations of prompting do not necessarily yield progressively improved behavior. As a general matter, due to the inherent unpredictability of ML models, users typically have to employ a large amount of guesswork before meaningful operations are performed.

One approach to improving the interactive trial-and-error prompting process described above is a technique known as fine-tuning. Fine-tuning involves re-training the generative ML model using additional training data. Once the fine-tuning process is complete, the user can sometimes write shorter and/or less detailed prompts and obtain satisfactory behavior. Occasionally the user can even obtain useful behavior with fewer interactions. However, one drawback of fine-tuning is that the additional training data usually needs to be manually created by the user or model developer. Another drawback of fine-tuning is that, after fine tuning, the generative ML model may still be unable to perform certain types of operations that are not explicitly included in the additional training data.

As the foregoing illustrates, what is needed in the art are more effective techniques for interacting with generative ML models.

### SUMMARY

In various embodiments, a computer-implemented method for generating prompt inputs that describe design modifications includes receiving a first prompt input that indicates a first modification to a three-dimensional (3D) design, determining a first context input based on one or more attributes of the 3D design, and causing a first generative machine learning (ML) model to generate a second prompt input based on the first prompt input and the first context input, where the second prompt input indicates a second modification to the 3D design.

At least one technical advantage of the disclosed techniques relative to the prior art is that the disclosed techniques enable generative ML models to produce detailed and accurate prompts that specifically describe design modifications, without requiring the user to iteratively refine prompts in an indefinite and unpredictable manner. Accordingly, the user can obtain prompts that are more effective when interacting with a generative ML model to generate desired designs or design modifications. Another technical advantage of the disclosed techniques is that fine-tuning is not needed to cause a generative ML model to produce accurate responses to user prompts. Therefore, the additional training data typically used in fine-tuning does not need to be created when implementing the disclosed techniques. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design modification application and the prompt modification application of FIG. 1, according to various embodiments;

FIGS. 3A-3C are exemplar illustrations of the design space and the prompt space of FIG. 2, according to various embodiments;

FIG. 4 sets forth a flow diagram of method steps for generating a prompt modification and a design modification based on a catalog of prompts, according to various embodiments; and

FIG. 5 depicts one architecture of a system within which the various embodiments of the present disclosure may be implemented

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

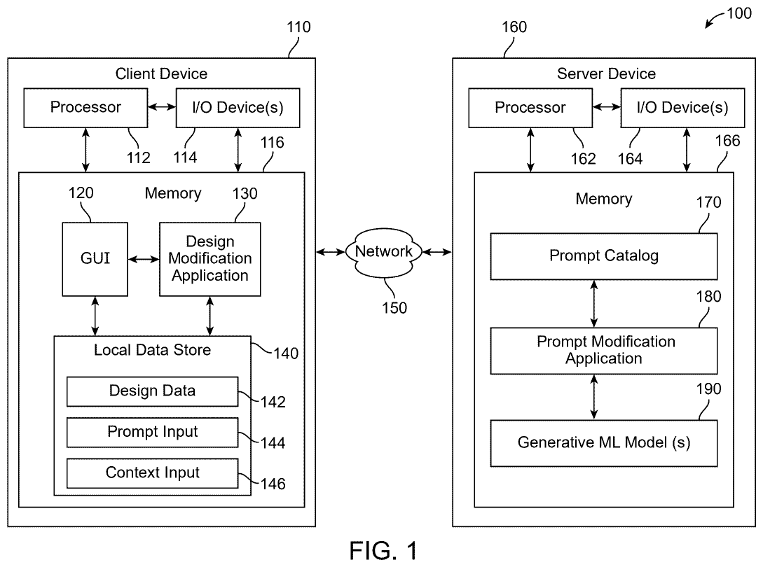

FIG. 1 is a conceptual illustration of a system 100 configured to implement one or more aspects of the various embodiments. As shown, in some embodiments, the system 100 includes, without limitation, a client device 110 and a server device 160. The client device 110 includes, without limitation, a processor 112, one or more input/output (I/O) devices 114, and a memory 116. The memory 116 includes, without limitation, a graphical user interface (GUI) 120, a design modification application 130, and a local data store 140. The local data store 140 includes, without limitation, design data 142, prompt input 144, and context input 146. The server device 160 includes, without limitation, a processor 162, one or more I/O devices 164, and a memory 166. The memory 166 includes, without limitation, a prompt catalog 170, a prompt modification application 180, and generative ML model(s) 190. In some other embodiments, the system 100 can include any number and/or types of other client devices, server devices, additional ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design modification application 130 that allows a user to generate design modifications to a three-dimensional (3D) design that is defined by design data 142. In various embodiments, design data 142 may include any technically feasible definition of 3D geometry. In operation, the design modification application 130 receives the prompt input 144 from the user, where the prompt input 144 describes one or more design modifications to the 3D design. The prompt modification application 180 then generates alternative versions of the prompt input 144 that include a higher degree of detail. Based on the alternative version(s) of the prompt input 144, the design modification application 130 can implement the desired design modifications.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design modification application 130, and data (e.g., the design data 142, the prompt input 144, and the context input 146 stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design modification application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design modification application 130 resides in the memory 116 and executes on the processor 112 of the client device 110. The design modification application 130 interacts with the user via the GUI 120. In some embodiments, the design modification application 130 and one or more separate applications (not shown) interact with the same user via the GUI 120. In various embodiments, the design modification application 130 interacts with the user via the GUI 120 to display the 3D model associated with design data 142 to the user.

The GUI 120 receives the prompt input 144 from the user and generates the context input 146 based on one or more interactions between the user and GUI 120. The prompt input 144 includes text that may refer to the 3D design defined by design data 142. The context input 146 generally indicates one or more attributes of that 3D design. For example, and without limitation, the context input 146 could include a portion of geometry associated with the 3D design and/or a current viewing angle from which GUI 120 generates a rendering of the 3D design. In various embodiments, the context input 146 may further include a cursor location corresponding to a position within design data 142 and/or a selected region of the 3D design. The design modification application 130 transmits the prompt input 144 and the context input 146 to the prompt modification application 180 for further processing. In one embodiment, the design modification application 130 may generate a compound prompt that includes both the prompt input 144 and the context input 146.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design modification application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design modification application 130 organizes GUI elements into one or more container GUI elements (e.g., panels and/or panes).

The network 150 can be any technically feasible set of interconnected communication links, including a local area network (LAN), wide area network (WAN), the World Wide Web, or the Internet, among others. The network 150 enables communications between the client device 110 and other devices in the network 150 via wired and/or wireless communications protocols, including Bluetooth, Bluetooth low energy (BLE), wireless local area network (WiFi), cellular protocols, satellite networks, and/or near-field communications (NFC).

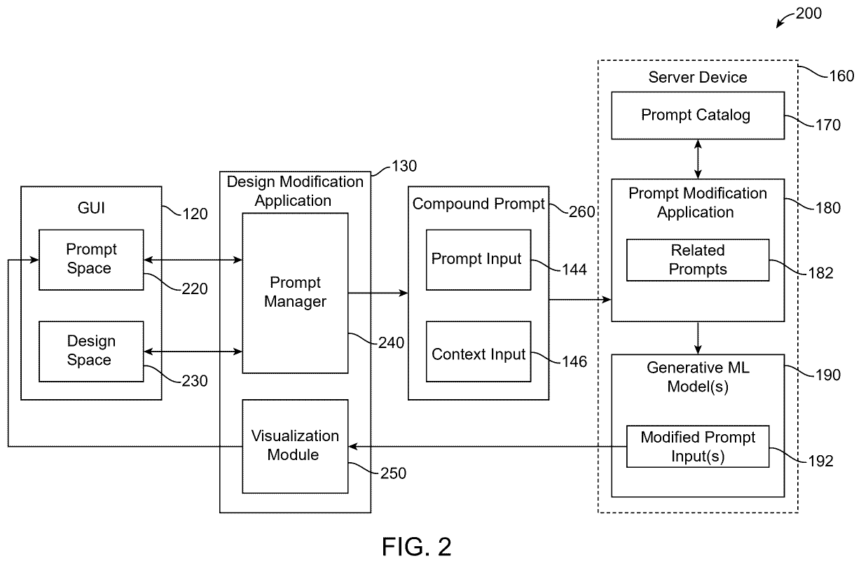

The server device 160 is configured to communicate with the design modification application 130 to process the prompt input 144 and the context input 146. In operation, the server device 160 executes the prompt modification application 180 to generate one or more modified prompt inputs based on the prompt input 144, the context input 146, and prompt catalog 170. The one or more modified prompt inputs may represent alternative versions of the prompt input 144 that have a higher degree of descriptive detail and/or accuracy than the prompt input 144. In various embodiments, prompt modification application 180 may implement the generative ML model(s) 190 to generate the one or more modified prompt inputs based on the prompt input 144, the context input 146, and one or more related prompts derived from prompt catalog 170, as described in greater detail below in conjunction with FIG. 2.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, The I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the prompt modification application 180 and the generative ML model(s) 190, and data (e.g., the prompt catalog 170) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the prompt modification application 180 and/or the generative ML models 190 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, the server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the prompt modification application 180 could be executed on the client device 110 and can communicate with the generative ML model(s) 190 operating at the server device 160.

In various embodiments, the prompt modification application 180 receives various inputs from the design modification application 130, including the prompt input 144 and the context input 146, and based on those inputs retrieves a set of related prompts from prompt catalog 170. The prompt catalog 170 generally includes a library of other prompts that may be contextually relevant to the 3D design, including one or more recent prompts input by the user or other users, a history of prompts associated with a team to which the user belongs, a set of prompts commonly used in the industry where the user typically operates, one or more prompts historically associated with the type of 3D design the user currently generates, and so forth, for example and without limitation.

Prompt modification application 180 inputs the prompt input 144, the context input 146, and the one or more related prompts 170 to generative ML model(s) 190. In response, the generative ML model(s) 190 generates a modified prompt input that describes a modification to the 3D design described by design data 142. A given modified prompt input is a more detailed and potentially more accurate version of prompt input 144. In one embodiment, a modified prompt input may include prompt input 144 and also include additional contextually-relevant text generated by generative ML model(s) 190 to provide additional detail regarding a desired modification to the 3D design. In another embodiment, a modified prompt input may include an altered version of prompt input 144, modified by the generative ML model(s) 190 to more accurately describe the modification to the 3D design. Based on the modified prompt input, design modification application 130 modifies design data 142. GUI 120 may then display an updated rendering of the 3D design associated with design data 142.

In some embodiments, one or more of the generative ML model(s) 190 are trained to respond to specific types of inputs, such as an ML model that is trained to generate text-based responses from a specific combination of modalities (e.g., text and images). In such instances, the prompt modification application 180 processes various inputs to determine the modalities of the data included therein and identifies one or more of the ML model(s) 190 that have been trained to respond to such a combination of modalities. Upon identifying the one or more ML models 190, the prompt modification application 180 selects an ML model and inputs the prompt into the selected ML model 190.

The generative ML model(s) 190 include one or more ML models that have been trained on a relatively large amount of existing data to perform any number and/or types of prediction tasks based on patterns detected in the existing data. In some embodiments, a given trained ML model 190 is trained using various combinations of data from multiple modalities, such as textual data, image data, sound data, and so forth. The generative ML model(s) 190 that are trained using at least two modalities of data are also referred to herein as multimodal ML model(s). For example, in some embodiments, one or more trained ML models 190 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth.

FIG. 2 is a more detailed illustration of the design modification application 130 and the prompt modification application 180 of FIG. 1, according to various embodiments. As shown, in some embodiments, a system 200 includes, without limitation, the GUI 120, the design modification application 130, and the server device 160. The GUI 120 includes, without limitation, a prompt space 220 and a design space 230. The design modification application 130 includes, without limitation, a prompt manager 240 and a visualization module 250. The server device 160 includes, without limitation, the domain catalog 170, the prompt modification application 180, and the generative ML model(s) 190.

For explanatory purposes only, the functionality of the design modification application 130 and the prompt modification application 180 is described herein in the context of exemplar interactive and linear workflows. As persons skilled in the art will recognize, the techniques described herein are illustrative rather than restrictive and can be altered and applied in other contexts without departing from the broader spirit and scope of the inventive concepts described herein.

In operation, the visualization module 250 generates the GUI 120, including the prompt space 220 and the design space 230. The prompt space 220 generally includes GUI elements for receiving text input. The design space 230 generally includes GUI elements for displaying 3D renderings of the 3D model described by the design data 142. The design space 230 also includes GUI elements that allow the user to select portions of such images, including a cursor, among others. The prompt manager 240 interacts with the prompt space 220 to obtain the prompt input 144 from the user. The prompt manager 240 also interacts with the design space 230 to obtain the context input 146, including selections made by the user as well as viewing information associated with 3D renderings.

As a general matter, the prompt input 144 is a text prompt that describes, to some degree, what design space 230 should display. In some embodiments, prompt input 144 may describe specific imagery that should be displayed. For example, and without limitation, prompt input 144 could describe, with a given level of detail, a particular scene that design space 230 should display. In other embodiments, prompt input 144 may describe modifications that should be made to a 3D design displayed via design space 230. For example, and without limitation, prompt input 144 could describe, with a given level of detail, that a hole should be placed in a 3D design displayed via design space 230.

The context input 146 includes contextual data that is derived from user interactions with the design space 230. For example, and without limitation, the context input 146 could include a user selection of a portion of a 3D rendering, or a user selected viewing angle, among others. In various embodiments, the context input 146 may also include a set of applications the user has recently used or is currently using, a set of design tools the user has recently used or is currently using to modify the 3D design, a determined skill level associated with the user relative to a given task, or a current mode of operation associated with the design modification application 130.

The prompt manager 240 generates a compound prompt 260 to include both the prompt input 144 and the context input 146. In one embodiment, the compound prompt 260 may be a multimodal prompt that includes data associated with two distinct modalities. For example, and without limitation, the prompt input 144 could include text, while the context input 146 could include one or more images. In various other embodiments, the prompt input 144 and the context input 146 correspond to a single modality (e.g., text only).

The prompt modification application 180 is configured to access prompt catalog 170 and retrieve a set of prompts that are contextually relevant to prompt input 144 and/or context input 146 within compound prompt 260. As described, the prompt catalog 170 generally includes a library of other prompts, and may include one or more recent prompts input by the user or other users, a history of prompts associated with a team to which the user belongs, a set of prompts commonly used in the industry where the user typically operates, one or more prompts historically associated with the type of 3D design the user currently generates, and so forth, for example and without limitation. In one embodiment, the set of related prompts 182 may be ranked according to a metric that reflects how frequently or successfully each related prompt has previously been used. The prompt modification application 180 accesses the prompt catalog 170 based on compound prompt 260 and extracts related prompts 182.

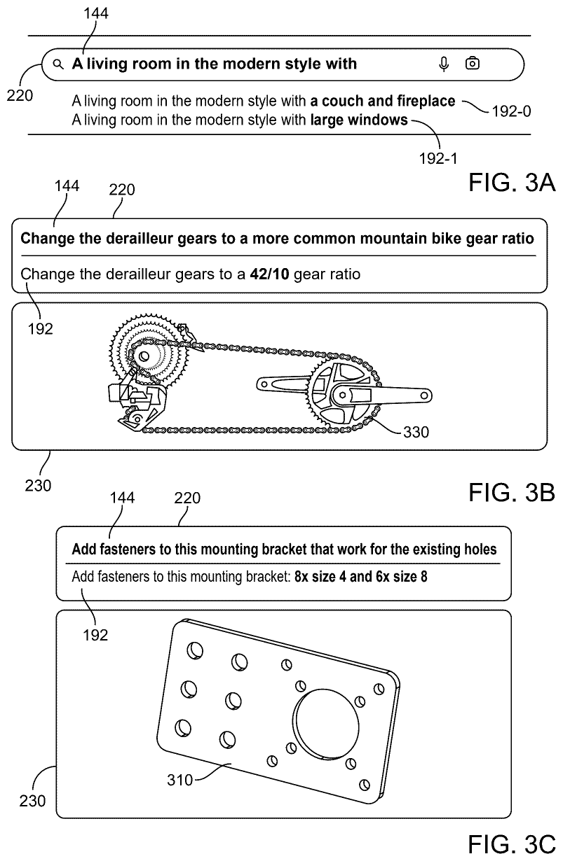

The prompt modification application 180 then causes the generative ML model(s) 190 to process compound prompt 260 in conjunction with related prompts 182 in order to generate modified prompt input(s) 192. Modified prompt input(s) 192 include one or more alternative text prompts that generally represent improved versions of prompt input 144. The generative ML model(s) 190 can generate modified prompt inputs(s) 192 by adding additional language to prompt input 144, thereby adding descriptive detail, or by modifying prompt input 144 to increase descriptive precision, as described by way of example below in conjunction with FIGS. 3A-3B.

FIGS. 3A-3C are exemplar illustrations of the prompt space and the design space of FIG. 2, according to various embodiments. As shown in FIG. 3A, prompt space 220 includes prompt input 144 that describe, in general terms, imagery associated with a living room. In operation, the design modification application 130 receives prompt input 144 and generates any relevant context input 146. The prompt modification application 180 retrieves one or more related prompts 182 from prompt catalog 170, and the generative ML model(s) 190 then generate modified prompt input(s) 192-0 and 192-1.

In the example shown, modified prompt inputs 192-0 and 192-1 are alternative versions of prompt input 144 that are extended with additional text to provide further detail. In this manner, prompt modification application 180 assists the user with generating descriptive prompts by providing a set of suggestions. The user can then select between modified prompt inputs 192, and design modification application 130 can then update design space 230 based on the selected modified prompt input 192. In so doing, design modification application 130 can implement the generative ML model(s) 190 to generate specific design modifications. In addition to extending prompt inputs, prompt modification application 180 can also generate different versions of prompt inputs, as mentioned above and as described in greater detail below in conjunction with FIG. 3B.

As shown in FIG. 3B, prompt space 220 includes prompt input 144 that generally describes a change to the gear ratio associated with a 3D design 300 that represents a set of mountain bike gears. In operation, the design modification application 130 receives prompt input 144 and generates context input 146. In this example, the context input 146 could include, without limitation, a portion of the design data 142 that describes a current gear ratio, a portion of geometry derived from 3D design 300, or a portion of a rendering of 3D design 300, without limitation. Context input 146 could further indicate a set of common mountain bike gear ratios associated with the mountain bike industry or a team of mountain bike engineers with which the user interacts. In one embodiment, the design modification application 130 or the prompt modification application 180 may analyze the prompt input 144 and gather relevant context in order to resolve ambiguous or vague descriptive text. In the example described, the design modification application 130 or the prompt modification application 180 could resolve the text “a more common mountain bike gear ratio” to a specific gear ratio that is determined to be common, using various contextual factors, as needed. Based on the prompt input 144 and the context input 146, the prompt modification application 180 then retrieves one or more related prompts 182 from prompt catalog 170. The generative ML model(s) 190 then generate a modified prompt input 190.

The modified prompt input 192 in the example shown is a more detailed version of the prompt input 144, updated to include specific details of the mountain bike gear ratio. In the manner described, prompt modification application 180 assists the user with generating prompts that have a higher degree of accuracy and detail. The user can select the modified prompt inputs 192, and the design modification application 130 can then update the design data 142 with specific design modifications expressed in the modified prompt input 192. Design modification application 130 can implement the generative ML model(s) 190, in any technically feasible fashion, to generate those design modifications. FIG. 3C sets forth another example of how prompt modification application 180 assists the user with developing more detailed and accurate prompts.

As shown in FIG. 3C, prompt space 220 includes prompt input 144 that generally describes an addition the user wants to make to a 3D design. Here, the user wants to add fasteners to a mounting bracket that are specifically tailored to be compatible with an existing set of holes. In response to prompt input 144, the design modification application 130 generates context input 146. In this example, without limitation, the context input 146 could include specific design geometry that reflects the existing placement of holes. Based on the prompt input 144 and context input 146, the prompt modification application 180 then retrieves one or more related prompts 182 from prompt catalog 170. The generative ML model(s) 190 then generate the modified prompt input 192.

The modified prompt input 192 is an alternate version of the prompt input 144 that is updated to include specific text describing the current placement of holes on the mounting bracket. Accordingly, modified prompt input 192 more specifically indicates a desired positioning for the requested fasteners. In this manner, prompt modification application 180 generates modified prompt inputs that describe design changes with a higher degree of accuracy than prompt inputs received from the user. When the user selects modified prompt input 192, the design modification application 130 then updates the design data 142 with the specific design modifications expressed in the modified prompt input 192. Design modification application 130 can implement the generative ML model(s) 190, in any technically feasible fashion, to generate those design modifications and update design data 142.

Referring generally to FIGS. 3A-3C, through the techniques described above, the design modification application 130 and the prompt modification application 180 interoperate to generate modified prompts that more specifically describe a desired set of design modifications. These design modifications can then be applied to a 3D design. This approach streamlines the conventional iterative prompting process by assisting the user with more detailed and more descriptive prompts that are contextually relevant and directly pertinent to the 3D design.

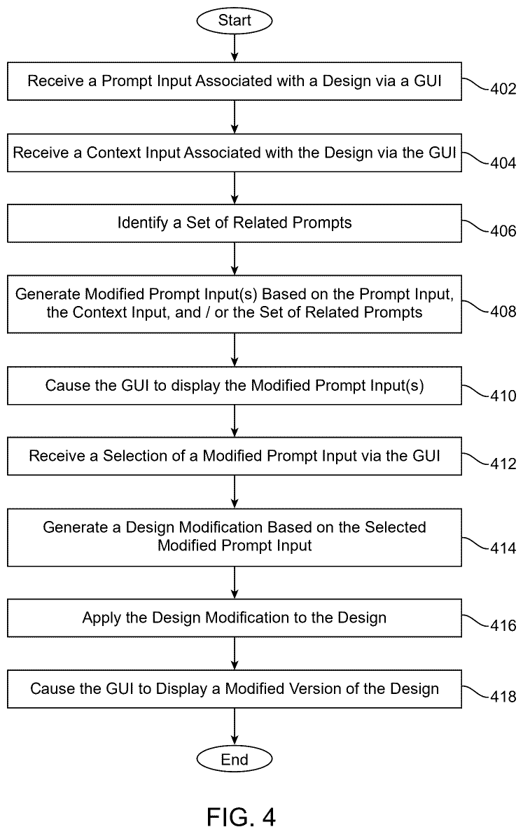

FIG. 4 sets forth a flow diagram of method steps for generating a prompt modification and a design modification based on a catalog of prompts, according to various embodiments. Although the method steps are described with reference to the systems of FIGS. 1-3C, persons skilled in the art will understand that any system configured to implement the method steps, in any order, falls within the scope of the embodiments.

As shown, a method 400 begins at step 402, where the design modification engine 130 receives the prompt input 144 via GUI 120. The prompt input 144 generally corresponds to a 3D design that is described via design data 142. The GUI 120 is configured to display a 3D rendering of the design to the user via the design space 230. The prompt input 144 is received via prompt space 220 within GUI 120.

At step 404, the design modification engine 130 receives the context input 146 via the GUI 120. The context input 146 includes contextual information associated with the 3D design and/or various user interactions with the 3D design. For example, and without limitation, the context input 146 could include a user selection of a portion of the 3D design, a current viewing angle of the 3D design, a portion of the 3D design referenced by the prompt input 144, or various metadata describing one or more attributes of the 3D design. In one embodiment, the design modification engine 130 generates a compound prompt 260 that includes the prompt input 144 and the context input 146 and transmits the compound prompt 260 to the prompt modification application 180 for further processing.

At step 406, prompt modification application 180 accesses prompt catalog 170 to identify the set of related prompts 182. The prompt catalog 170 generally includes a library of other prompts, and may include one or more recent prompts input by the user or other users, a history of prompts associated with a team to which the user belongs, a set of prompts commonly used in the industry where the user typically operates, one or more prompts historically associated with the type of 3D design the user currently generates, and so forth, for example and without limitation.

At step 408, prompt modification application 180 causes one or more of the generative ML model(s) 190 to generate the modified prompt input(s) 192 based on the prompt input 144, the context input 146, and/or the set of related prompts 182. In one embodiment, the prompt modification application 180 may select a domain-specific generative ML model 190 based on the specific content and/or context associated with prompt input 144. For example, and without limitation, prompt modification application 180 could select a generative ML model 190 that is specifically trained and/or fine-tuned with data pertaining to electrical engineering in order to generate one or more modified prompt input(s) 192 that are relevant to a prompt input 144 associated with electrical engineering.

At step 410, design modification application 130 causes the GUI 120 to display the modified prompt input(s) 192. The GUI 120 displays the modified prompt input(s) 192 within the prompt space 220 in the manner shown by way of example in FIGS. 3A-3C. In various embodiments, the GUI 120 displays the modified prompt input(s) 192 in conjunction with the prompt input 144 as suggested alternatives to the prompt input 144. The GUI 120 can display the modified prompt input(s) 192 as a drop-down list beneath the prompt input 144, for example and without limitation.

At step 412, the GUI 120 receives a selection of one of the modified prompt input(s) 192 from the user. The modified prompt input 192 selected by the user may describe specific design modifications the user wants to make to the 3D design displayed via design space 230. The modified prompt input 192 may include the prompt input 144 along with additional descriptive text provided via prompt modification application 180 or, alternatively, may include an updated version of the prompt input 144 that is modified to increase specificity, accuracy, and/or detail.

At step 412, design modification application 130 generates a design modification based on the selected modified prompt input 192. In one embodiment, the design modification application 130 may implement one or more of the generative ML model(s) 190 to generate the design modifications based on a current state of the 3D design described via the design data 142. At step 416, the design modification engine 130 applies the design modification to the design. In so doing, the design modification engine 130 may implement various generative techniques to produce 3D geometry representing an updated version of the 3D design. At step 418, the design modification engine 130 causes the GUI 120 to display a modified version of the design.

### System Implementation

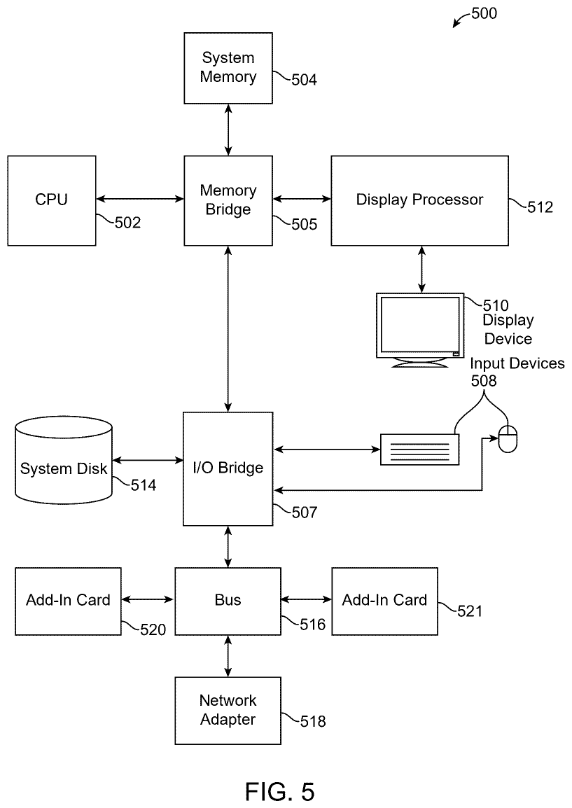

FIG. 5 depicts one architecture of a system 500 within which embodiments of the present disclosure may be implemented. This figure in no way limits or is intended to limit the scope of the present disclosure. In various implementations, system 500 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 500 may be coupled together to practice one or more aspects of the present disclosure.

As shown, system 500 includes a central processing unit (CPU) 502 and a system memory 504 communicating via a bus path that may include a memory bridge 505. CPU 502 includes one or more processing cores, and, in operation, CPU 502 is the master processor of system 500, controlling and coordinating operations of other system components. System memory 504 stores software applications and data for use by CPU 502. CPU 502 runs software applications and optionally an operating system. Memory bridge 505, which may be, e.g., a Northbridge chip, is connected via a bus or other communication path (e.g., a HyperTransport link) to an I/O (input/output) bridge 507. I/O bridge 507, which may be, e.g., a Southbridge chip, receives user input from one or more user input devices 508 (e.g., keyboard, mouse, joystick, digitizer tablets, touch pads, touch screens, still or video cameras, motion sensors, and/or microphones) and forwards the input to CPU 502 via memory bridge 505.

A display processor 512 is coupled to memory bridge 505 via a bus or other communication path (e.g., a PCI Express, Accelerated Graphics Port, or HyperTransport link); in one embodiment display processor 512 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 504.

Display processor 512 periodically delivers pixels to a display device 5110 (e.g., a screen or conventional CRT, plasma, OLED, SED or LCD based monitor or television). Additionally, display processor 512 may output pixels to film recorders adapted to reproduce computer generated images on photographic film. Display processor 512 can provide display device 510 with an analog or digital signal. In various embodiments, one or more of the various graphical user interfaces set forth in Appendices A-J, attached hereto, are displayed to one or more users via display device 510, and the one or more users can input data into and receive visual output from those various graphical user interfaces.

A system disk 514 is also connected to I/O bridge 507 and may be configured to store content and applications and data for use by CPU 502 and display processor 512. System disk 514 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 516 provides connections between I/O bridge 507 and other components such as a network adapter 518 and various add-in cards 520 and 521. Network adapter 518 allows system 500 to communicate with other systems via an electronic communications network, and may include wired or wireless communication over local area networks and wide area networks such as the Internet.

Other components (not shown), including USB or other port connections, film recording devices, and the like, may also be connected to I/O bridge 507. For example, an audio processor may be used to generate analog or digital audio output from instructions and/or data provided by CPU 502, system memory 504, or system disk 514. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 512 incorporates circuitry optimized for graphics and video processing, including, for example, video output circuitry, and constitutes a graphics processing unit (GPU). In another embodiment, display processor 512 incorporates circuitry optimized for general purpose processing. In yet another embodiment, display processor 512 may be integrated with one or more other system elements, such as the memory bridge 505, CPU 502, and I/O bridge 507 to form a system on chip (SoC). In still further embodiments, display processor 512 is omitted and software executed by CPU 502 performs the functions of display processor 512.

Pixel data can be provided to display processor 512 directly from CPU 502. In some embodiments of the present disclosure, instructions and/or data representing a scene are provided to a render farm or a set of server computers, each similar to system 500, via network adapter 518 or system disk 514. The render farm generates one or more rendered images of the scene using the provided instructions and/or data. These rendered images may be stored on computer-readable media in a digital format and optionally returned to system 500 for display. Similarly, stereo image pairs processed by display processor 512 may be output to other systems for display, stored in system disk 514, or stored on computer-readable media in a digital format.

Alternatively, CPU 502 provides display processor 512 with data and/or instructions defining the desired output images, from which display processor 512 generates the pixel data of one or more output images, including characterizing and/or adjusting the offset between stereo image pairs. The data and/or instructions defining the desired output images can be stored in system memory 504 or graphics memory within display processor 512. In an embodiment, display processor 512 includes 3D rendering capabilities for generating pixel data for output images from instructions and data defining the geometry, lighting shading, texturing, motion, and/or camera parameters for a scene. Display processor 512 can further include one or more programmable execution units capable of executing shader programs, tone mapping programs, and the like.

Further, in other embodiments, CPU 502 or display processor 512 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 502, display processor 512, or one or more other processing devices or any combination of these different processors.

CPU 502, render farm, and/or display processor 512 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 500 may be a robot or robotic device and may include CPU 502 and/or other processing units or devices and system memory 504. In such embodiments, system 500 may or may not include other elements shown in FIG. 1. System memory 504 and/or other memory units or devices in system 500 may include instructions that, when executed, cause the robot or robotic device represented by system 500 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 504 is connected to CPU 502 directly rather than through a bridge, and other devices communicate with system memory 504 via memory bridge 505 and CPU 502. In other alternative topologies display processor 512 is connected to I/O bridge 507 or directly to CPU 502, rather than to memory bridge 505. In still other embodiments, I/O bridge 507 and memory bridge 505 might be integrated into a single chip. The particular components shown herein are optional; for instance, any number of add-in cards or peripheral devices might be supported. In some embodiments, switch 516 is eliminated, and network adapter 518 and add-in cards 520, 521 connect directly to I/O bridge 507.

In sum, a design modification application and a prompt modification application interoperate to generate one or more modified prompt inputs that describe various design modifications to a 3D design. The design modification application receives a prompt input from a user that describes, with some degree of accuracy, the various design modifications. The design modification application gathers context input associated with the design and then causes the prompt modification application to obtain a set of related prompts that are contextually relevant to the prompt input. The prompt modification application, in turn, causes a generative ML model to analyze the prompt input, the context input, and the set of related prompts to generate the one or more modified prompt inputs. A given modified prompt input describes, with a higher degree of accuracy, the various design modifications. The user can select between the different modified prompt inputs. Based on a given selection, the design modification application then updates the 3D design to reflect the various design modifications.

At least one technical advantage of the disclosed techniques relative to the prior art is that the disclosed techniques enable generative ML models to produce detailed and accurate prompts that specifically describe design modifications, without requiring the user to iteratively refine prompts in an indefinite and unpredictable manner. Accordingly, the user can obtain prompts that are more effective when interacting with a generative ML model to generate desired designs or design modifications. Another technical advantage of the disclosed techniques is that fine-tuning is not needed to cause a generative ML model to produce accurate responses to user prompts. Therefore, the additional training data typically used in fine-tuning does not need to be created when implementing the disclosed techniques. These technical advantages provide one or more technological advancements over prior art approaches.
1. Some embodiments include a computer-implemented method for generating prompt inputs that describe design modifications, the method comprising receiving a first prompt input that indicates a first modification to a three-dimensional (3D) design, determining a first context input based on one or more attributes of the 3D design, and causing a first generative machine learning (ML) model to generate a second prompt input based on the first prompt input and the first context input, wherein the second prompt input indicates a second modification to the 3D design.
2. The computer-implemented method of clause 1, wherein determining the first context input comprises determining a viewing position that is implemented via a graphical user interface to display the 3D design.
3. The computer-implemented method of any of clauses 1-2, wherein determining the first context input comprises receiving a user selection of a portion of the 3D design via a GUI that displays the 3D design.
4. The computer-implemented method of any of clauses 1-3, wherein determining the first context input comprises identifying a first portion of the 3D design based on the first prompt input.
5. The computer-implemented method of any of clauses 1-4, wherein determining the first context input comprises determining at least one design tool implemented by the user to generate the 3D design.
6. The computer-implemented method of any of clauses 1-5, further comprising obtaining one or more additional prompts from a prompt catalog based on the first prompt input and the first context input, wherein the prompt catalog includes a plurality of historical prompts, and wherein the second prompt is further generated based on the one or more additional prompts.
7. The computer-implemented method of any of clauses 1-6, wherein the second prompt is further generated based on a prompt history associated with a user.
8. The computer-implemented method of any of clauses 1-7, wherein the second prompt input includes the first prompt input and further includes additional descriptive text that describes the second modification to the 3D design.
9. The computer-implemented method of any of clauses 1-8, wherein generating the second prompt input comprises modifying at least a portion of the first prompt input based on the first context input.
10. The computer-implemented method of any of clauses 1-9, further comprising causing a second generative ML model to modify the 3D design based on the second prompt input to implement the second design modification.
11. Various embodiments include one or more non-transitory computer-readable media including instructions that, when executed by one or more processors, cause the one or more processors to generate prompt inputs that describe design modifications by performing the steps of receiving a first prompt input that indicates a first modification to a three-dimensional (3D) design, determining a first context input based on one or more attributes of the 3D design, and causing a first generative machine learning (ML) model to generate a second prompt input based on the first prompt input and the first context input, wherein the second prompt input indicates a second modification to the 3D design.
12. The one or more non-transitory computer-readable media of clause 11, wherein the step of determining the first context input comprises determining a viewing position that is implemented via a graphical user interface to display the 3D design.
13. The one or more non-transitory computer-readable media of any of clauses 11-12, wherein the step of determining the first context input comprises receiving a user selection of a portion of the 3D design via a GUI that displays the 3D design.
14. The one or more non-transitory computer-readable media of any of clauses 11-13, wherein the step of determining the first context input comprises identifying a first portion of the 3D design based on the first prompt input.
15. The one or more non-transitory computer-readable media of any of clauses 11-14, wherein the step of determining the first context input comprises determining at least one design tool implemented by the user to generate the 3D design.
16. The one or more non-transitory computer-readable media of any of clauses 11-15, further comprising the step of obtaining one or more additional prompts from a prompt catalog based on the first prompt input and the first context input, wherein the prompt catalog includes a prompt history associated with a user that provides the first prompt input, and wherein the second prompt is further generated based on the one or more additional prompts.
17. The one or more non-transitory computer-readable media of any of clauses 11-16, further comprising the step of causing a second generative ML model to modify the 3D design based on the second prompt input to implement the second design modification.
18. The one or more non-transitory computer-readable media of any of clauses 11-17, further comprising the steps of causing the first generative ML model to generate a third prompt input based on the first prompt input and the first context input, wherein the third prompt input indicates a third modification to the 3D design, causing a graphical user interface to display the first prompt input, the second prompt input, and the third prompt input, and receiving a selection of at least one of first prompt input, the second prompt input, or the third prompt input from the user.
19. The one or more non-transitory computer-readable media of any of clauses 11-18, wherein the second prompt input includes a greater number of characters than the first prompt input.
20. Some embodiments include a system comprising one or more memories storing instructions, and one or more processors coupled to the one or more memories that, when executing the instructions, perform the steps of receiving a first prompt input that indicates a first modification to a three-dimensional (3D) design, determining a first context input based on one or more attributes of the 3D design, and causing a first generative machine learning (ML) model to generate a second prompt input based on the first prompt input and the first context input, wherein the second prompt input indicates a second modification to the 3D design.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating prompt inputs that describe design modifications, the method comprising:
receiving a first prompt input that indicates a first modification to a three-dimensional (3D) design;
determining a first context input based on one or more attributes of the 3D design; and
causing a first generative machine learning (ML) model to generate a second prompt input based on the first prompt input and the first context input, wherein the second prompt input indicates a second modification to the 3D design.

2. The computer-implemented method of claim 1, wherein determining the first context input comprises determining a viewing position that is implemented via a graphical user interface to display the 3D design.

3. The computer-implemented method of claim 1, wherein determining the first context input comprises receiving a user selection of a portion of the 3D design via a GUI that displays the 3D design.

4. The computer-implemented method of claim 1, wherein determining the first context input comprises identifying a first portion of the 3D design based on the first prompt input.

5. The computer-implemented method of claim 1, wherein determining the first context input comprises determining at least one design tool implemented by the user to generate the 3D design.

6. The computer-implemented method of claim 1, further comprising obtaining one or more additional prompts from a prompt catalog based on the first prompt input and the first context input, wherein the prompt catalog includes a plurality of historical prompts, and wherein the second prompt is further generated based on the one or more additional prompts.

7. The computer-implemented method of claim 1, wherein the second prompt is further generated based on a prompt history associated with a user.

8. The computer-implemented method of claim 1, wherein the second prompt input includes the first prompt input and further includes additional descriptive text that describes the second modification to the 3D design.

9. The computer-implemented method of claim 1, wherein generating the second prompt input comprises modifying at least a portion of the first prompt input based on the first context input.

10. The computer-implemented method of claim 1, further comprising causing a second generative ML model to modify the 3D design based on the second prompt input to implement the second design modification.

11. One or more non-transitory computer-readable media including instructions that, when executed by one or more processors, cause the one or more processors to generate prompt inputs that describe design modifications by performing the steps of:
receiving a first prompt input that indicates a first modification to a three-dimensional (3D) design;
determining a first context input based on one or more attributes of the 3D design; and
causing a first generative machine learning (ML) model to generate a second prompt input based on the first prompt input and the first context input, wherein the second prompt input indicates a second modification to the 3D design.

12. The one or more non-transitory computer-readable media of claim 11, wherein the step of determining the first context input comprises determining a viewing position that is implemented via a graphical user interface to display the 3D design.

13. The one or more non-transitory computer-readable media of claim 11, wherein the step of determining the first context input comprises receiving a user selection of a portion of the 3D design via a GUI that displays the 3D design.

14. The one or more non-transitory computer-readable media of claim 11, wherein the step of determining the first context input comprises identifying a first portion of the 3D design based on the first prompt input.

15. The one or more non-transitory computer-readable media of claim 11, wherein the step of determining the first context input comprises determining at least one design tool implemented by the user to generate the 3D design.

16. The one or more non-transitory computer-readable media of claim 11, further comprising the step of obtaining one or more additional prompts from a prompt catalog based on the first prompt input and the first context input, wherein the prompt catalog includes a prompt history associated with a user that provides the first prompt input, and wherein the second prompt is further generated based on the one or more additional prompts.

17. The one or more non-transitory computer-readable media of claim 11, further comprising the step of causing a second generative ML model to modify the 3D design based on the second prompt input to implement the second design modification.

18. The one or more non-transitory computer-readable media of claim 11, further comprising the steps of:
causing the first generative ML model to generate a third prompt input based on the first prompt input and the first context input, wherein the third prompt input indicates a third modification to the 3D design;
causing a graphical user interface to display the first prompt input, the second prompt input, and the third prompt input; and
receiving a selection of at least one of first prompt input, the second prompt input, or the third prompt input from the user.

19. The one or more non-transitory computer-readable media of claim 11, wherein the second prompt input includes a greater number of characters than the first prompt input.

20. A system comprising:
one or more memories storing instructions; and
one or more processors coupled to the one or more memories that, when executing the instructions, perform the steps of:
receiving a first prompt input that indicates a first modification to a three-dimensional (3D) design;
determining a first context input based on one or more attributes of the 3D design; and
causing a first generative machine learning (ML) model to generate a second prompt input based on the first prompt input and the first context input, wherein the second prompt input indicates a second modification to the 3D design.
